(19) United States
(12) Patent Application Publication
(10) Pub. No.: US 2016/0164198 A1
(43) Pub. Date: Jun. 9, 2016

(54) Modular Connector Launch for a Printed Circuit Board

(71) Applicant: NATIONAL INSTRUMENTS CORPORATION, Austin, TX (US)

(72) Inventors: Ivan E. Hammer, Santa Rosa, CA (US); Ron L. Leidl, Sebastopol, CA (US); Andrew C. Fischer, Concord, CA (US); Abdolreza Karbassi, San Francisco, CA (US); Tamir E. Moran, Petaluma, CA (US); Gregory S. Gonzales, Sebastopol, CA (US)

(21) Appl. No.: 14/559,497

(22) Filed: Dec. 3, 2014

(51) Int. Cl. H01R 9/05; H05K 1/18; H01R 12/72; H05K 3/30

(52) U.S. Cl. CPC H01R 9/0515; H05K 3/301; H05K 1/18; H01R 12/722

(57) ABSTRACT

A connector launch configured for attachment to a printed circuit board (PCB). The connector launch may include a first attachment member that is configured for surface mount attachment over at least one trace of the PCB. The at least one trace of the PCB may be configured for coupling to the connector launch. The first attachment member may include a connector receptacle that is configured to receive a first connector of a plurality of possible connectors. The connector launch may further include a connector launch pin that is configured to couple to the at least one trace of the PCB within the first attachment member and extend into the connector receptacle. The connector launch pin may couple to a connector pin of the first connector when the first connector is connected to the connector receptacle.

### FIELD OF THE INVENTION

The present invention relates to the field of connector launches, and more particularly to a modular connector launch for a printed circuit board.

### DESCRIPTION OF THE RELATED ART

In many fields, such as radio frequency and/or microwave testing, printed circuit boards (PCBs) or printed circuit board assemblies (PCAs) include capabilities to connect to external devices, e.g., for testing. For example, such PCBs or PCAs may include a connector launch for coupling a device under test (DUT) to the PCA or PCB in order to perform testing of the DUT. However, these connector launches may be prone to various issues, such as degraded frequency performance, isolation, manufacturing efficiency, end user damage, etc. Accordingly, improvements in connector launches are desired.

### SUMMARY OF THE INVENTION

Various embodiments of a modular connector launch for a printed circuit board are presented below.

A connector launch configured for attachment (e.g., surface mount attachment, such as during a primary component automated process) to a printed circuit board (PCB). The connector launch may include a first attachment member that is configured for surface mount attachment over at least one trace of the PCB. The at least one trace of the PCB may be configured for coupling to the connector launch. The first attachment member may include a connector receptacle that is configured to receive a first connector of a plurality of possible connectors.

The connector launch may further include a connector launch pin that is configured to couple to the at least one trace of the PCB within the first attachment member and extend into the connector receptacle. The connector launch pin may couple to a connector pin of the first connector when the first connector is connected to the connector receptacle. The connector launch pin may be attached to the first attachment member by a mechanically rigid dielectric material (e.g., a glass seal).

The connector launch may also include a screw cap receptacle for receiving a screw cap to form an enclosure over the at least one trace of the PCB after attachment to the PCB.

### BRIEF DESCRIPTION OF THE DRAWINGS

A better understanding of the present invention can be obtained when the following detailed description of the preferred embodiment is considered in conjunction with the following drawings, in which:

FIG. 1A illustrates an instrumentation control system according to one embodiment of the invention;

FIG. 1B illustrates an industrial automation system according to one embodiment of the invention;

FIGS. 2-4 illustrate exemplary connector launches, according to various embodiments; and

FIG. 5 is a flowchart diagram illustrating one embodiment of a method for attaching a connector launch to a PCB.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

### Terms

The following is a glossary of terms used in the present application:

Measurement Device—includes instruments, data acquisition devices, smart sensors, and any of various types of devices that are configured to acquire and/or store data. A measurement device may also optionally be further configured to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, and other similar types of devices. Exemplary “stand-alone” instruments include oscilloscopes, multimeters, signal analyzers, arbitrary waveform generators, spectroscopes, and similar measurement, test, or automation instruments.

A measurement device may be further configured to perform control functions, e.g., in response to analysis of the acquired or stored data. For example, the measurement device may send a control signal to an external system, such as a motion control system or to a sensor, in response to particular data. A measurement device may also be configured to perform automation functions, i.e., may receive and analyze data, and issue automation control signals in response.

Functional Unit (or Processing Element)—refers to various elements or combinations of elements. Processing elements include, for example, circuits such as an ASIC (Application Specific Integrated Circuit), portions or circuits of individual processor cores, entire processor cores, individual processors, programmable hardware devices such as a field programmable gate array (FPGA), and/or larger portions of systems that include multiple processors, as well as any combinations thereof.

Automatically—refers to an action or operation performed by a computer system (e.g., software executed by the computer system) or device (e.g., circuitry, programmable hardware elements, ASICs, etc.), without user input directly specifying or performing the action or operation. Thus the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

Concurrent—refers to parallel execution or performance, where tasks, processes, or programs are performed in an at least partially overlapping manner. For example, concurrency may be implemented using “strong” or strict parallelism, where tasks are performed (at least partially) in parallel on respective computational elements, or using “weak parallelism”, where the tasks are performed in an interleaved manner, e.g., by time multiplexing of execution threads.

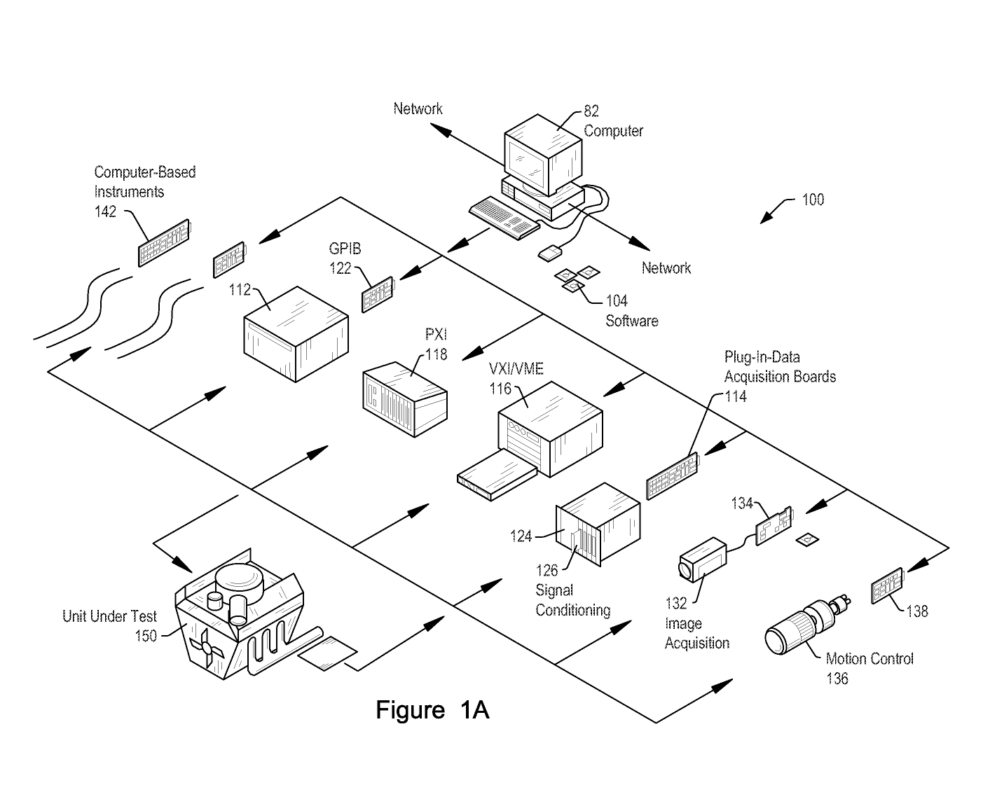

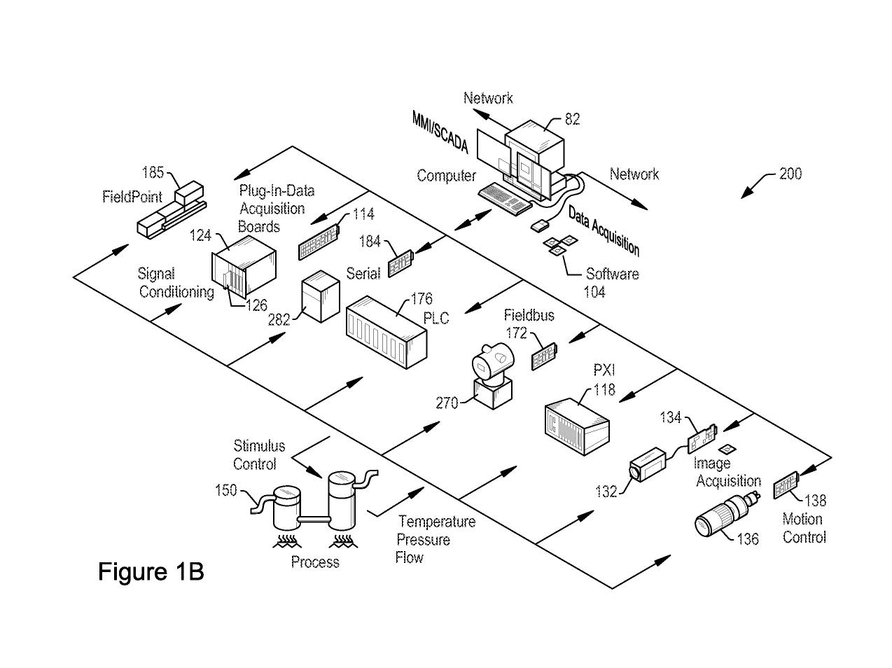

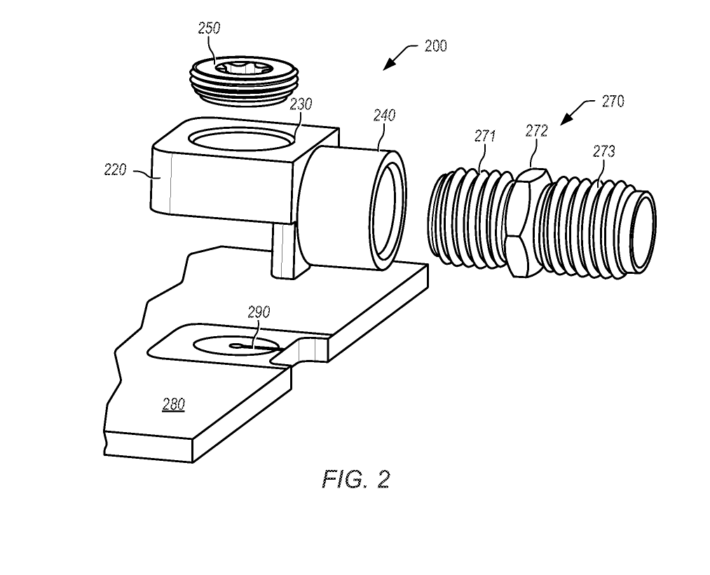

### FIGS. 1A and 1B

### Exemplary Systems

Embodiments of the present invention may be involved with performing test and/or measurement functions; controlling and/or modeling instrumentation or industrial automation hardware; modeling and simulation functions, e.g., modeling or simulating a device or product being developed or tested, etc. Exemplary test applications may include hardware-in-the-loop testing and rapid control prototyping, among others.

However, it is noted that embodiments of the present invention can be used for a plethora of applications and is not limited to the above applications. In other words, applications discussed in the present description are exemplary only, and embodiments of the present invention may be used in any of various types of systems. Thus, embodiments of the system and method of the present invention is configured to be used in any of various types of applications, including the control of other types of devices such as multimedia devices, video devices, audio devices, telephony devices, Internet devices, etc., as well as general purpose software applications such as word processing, spreadsheets, network control, network monitoring, financial applications, games, etc.

FIG. 1A illustrates an exemplary instrumentation control system 100 which may implement embodiments of the invention. The system 100 comprises a host computer 82 which couples to one or more instruments. The host computer 82 may comprise a CPU, a display screen, memory, and one or more input devices such as a mouse or keyboard as shown. The computer 82 may operate with the one or more instruments to analyze, measure or control a unit under test (UUT) or process 150, e.g., via execution of software 104.

The one or more instruments may include a GPIB instrument 112 and associated GPIB interface card 122, a data acquisition board 114 inserted into or otherwise coupled with chassis 124 with associated signal conditioning circuitry 126, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices. The computer system may couple to and operate with one or more of these instruments. The instruments may be coupled to the unit under test (UUT) or process 150, or may be coupled to receive field signals, typically generated by transducers. The system 100 may be used in a data acquisition and control application, in a test and measurement application, an image processing or machine vision application, a process control application, a man-machine interface application, a simulation application, or a hardware-in-the-loop validation application, among others.

FIG. 1B illustrates an exemplary industrial automation system 200 which may implement embodiments of the invention. The industrial automation system 200 is similar to the instrumentation or test and measurement system 100 shown in FIG. 1A. Elements which are similar or identical to elements in FIG. 1A have the same reference numerals for convenience. The system 200 may comprise a computer 82 which couples to one or more devices or instruments. The computer 82 may comprise a CPU, a display screen, memory, and one or more input devices such as a mouse or keyboard as shown. The computer 82 may operate with the one or more devices to perform an automation function with respect to a process or device 150, such as MMI (Man Machine Interface), SCADA (Supervisory Control and Data Acquisition), portable or distributed data acquisition, process control, advanced analysis, or other control, among others, e.g., via execution of software 104.

The one or more devices may include a data acquisition board 114 inserted into or otherwise coupled with chassis 124 with associated signal conditioning circuitry 126, a PXI instrument 118, a video device 132 and associated image acquisition card 134, a motion control device 136 and associated motion control interface card 138, a fieldbus device 270 and associated fieldbus interface card 172, a PLC (Programmable Logic Controller) 176, a serial instrument 282 and associated serial interface card 184, or a distributed data acquisition system, such as Fieldpoint system 185, available from National Instruments Corporation, among other types of devices.

### Connector Launch

Various embodiments of the connector launch (e.g., a radio frequency (RF) and/or microwave connector launch) described herein may provide advantages over prior connector launches, e.g., in the areas of RF frequency performance, isolation, manufacturing efficiency, and/or end user damage repair, among other areas. Various ones of the connector launches described herein may be in a modular form and/or enable viable use in applications greater than 40 GHz.

In particular, the connector launches described herein may provide a discreet modular RF/Microwave signal launch from/to a printed circuit board (PCB) assembly (PCA). The connector launches may enable automated placement and attachment during the normal primary component attachments to the PCA. Previous connector launches have generally required manual attachment methods or intensive secondary operations, which are undesirable. The connector launches described herein may greatly reduce the thermal expansion mismatch issues that can occur with other prior designs, e.g., that use polytetrafluoroethylene (PTFE) dielectrics. For example, connector launches described herein may be attached to the PCB at temperatures in excess of 300 degrees Celsius without any ill effects.

In addition, connector launches described herein may integrate superior RF shielding that is self-contained and can provide signal isolation without externally applied gaskets or shields. An optional screw cap, discussed below, may be included to even further increase the isolation potential. These connector launches may also provide mechanical de-coupling between the critical pin attachment point on the PCB trace and the external RF connector center pin, also discussed below. For such connector launches, the mechanical isolation of the center conductor may virtually eliminate the possibility of twisting or tearing the center pin from the PCB trace by end users of the connector. The mechanical separation may include a coaxial threaded receptacle that enables the selection of various connector genders or standard interfaces and much easier replacement of damaged connectors by the end user. Other flange mount field replaceable options usually require risky blind mating of the signal pin that can result in damage to the connector launch.

In one embodiment, the connector launch may comprise a precision machined receptacle with a rigidly mounted 50 Ohm feedthrough. The receptacle geometry may mate precisely to matching Printed Circuit Board (PCB) geometry details and attachment may be made soldering or using conductive adhesive such as epoxy. The receptacle may enable efficient automated application to the PCB, e.g., using industry standard processes. The matching trace geometry on the PCB and the launch geometries may be optimized to achieve both high frequency performance and reduce production variations on a variety of PCB constructions (e.g., different stack-ups, materials, thicknesses, configurations, etc.). The receptacle may be threaded coaxially with the 50 Ohm feedthrough and may accept a variety of RF connector standards and/or genders. The coaxial attachment detail may provide a more robust method for installation and replacement than flange mounting. A threaded cover plug may provide complete RF shielding and isolation of the launch.

The combination of frequency performance, RF shielding, connection flexibility, manufacturability, and robust field replacement capabilities provide benefits unparalleled by prior connector launch.

### FIGS. 2-4

### Various Embodiments of a Connector Launch

FIGS. 2-4 illustrate various embodiments of a connector launch.

In particular, FIG. 2 illustrates a modular connector launch 200 having a first attachment member 220. The attachment member 220 includes a screw cap receptacle 230 for receiving a screw cap 250 as well as a connector receptacle 240 for receiving a connector 270. The connector receptacle 240 may be threaded coaxially, as shown. The connector receptacle 240 may include an application of the Crushable Connector Interface described in U.S. Pat. No. 8,530,758, entitled “Crushable Connector Interface” and filed on Mar. 9, 2011, which is hereby incorporated by reference in its entirety, as though fully and completely set forth herein. This crushable connector interface may enable reduced electrical performance losses when connector 270 is installed into the connector receptacle 240.

The attachment member 220 is configured for attachment (e.g., surface mount attachment, such as during an automated primary component attachment process) to a printed circuit board (PCB) 280 which may comprise a printed circuit board assembly (PCA). The PCB 280 may include at least one trace (e.g., a copper trace) 290, which may include or couple to a via of the PCB.

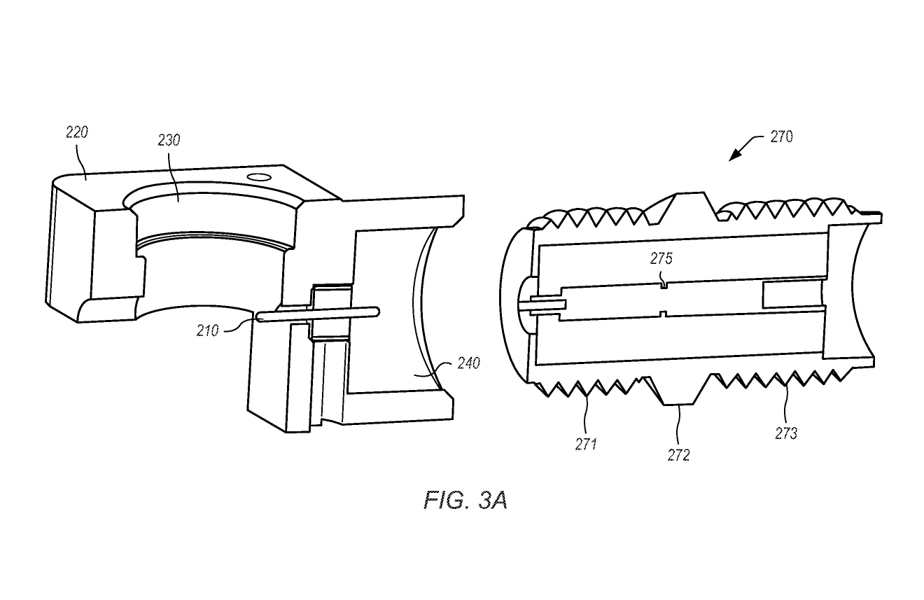

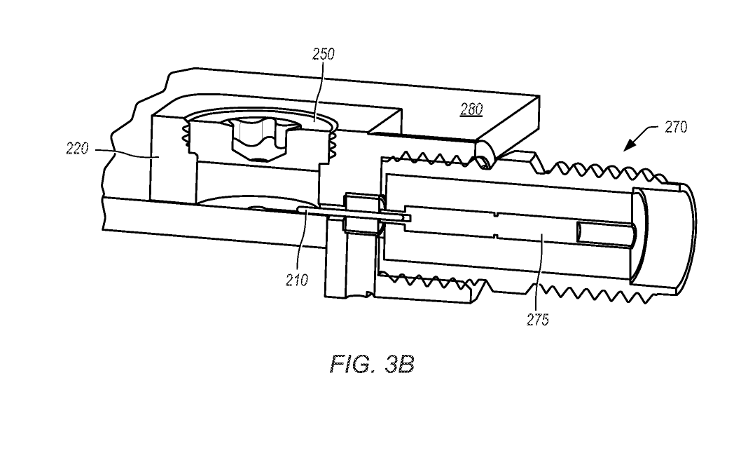

FIGS. 3A and 3B illustrate a cut-away version of the connector launch prior to and after coupling of the connector 270 to the connector receptacle 240. As shown in the cut-away of FIG. 3A, the connector may include a first portion 271 for coupling to the connector receptacle 240 and a second portion 273 for coupling to an external device (e.g., a DUT). These two portions may be separated by a hex nut or piece 272 that may allow facile attachment of the connector 270 to the connector receptacle 240 by the end user, e.g., without requiring the use of special tools. Although not shown, both the connector receptacle 240 and the screw cap receptacle 230 may be threaded to received threaded connector 270 and/or screw cap 250. Alternatively, items 230, 240, 250, and/or 270 may not be threaded and other connection types are envisioned.

Additionally, the connector launch 200 may include a connector launch pin 210 that is configured to couple to the at least one trace of the PCB 290 within the first attachment member 220 and extend into the connector receptacle 240. The connector launch pin 210 may couple to a connector pin 275 of the connector 270 when the connector 270 is connected to the connector receptacle 240, as shown in FIG. 3B. In the embodiment shown, the connector launch pin 210 may couple to the connector pin 275 as a male portion into female portion of the connector pin 275, although alternative embodiments are also envisioned, as desired.

The connector launch pin 210 may be attached to the first attachment member 220 by glass seal and/or other means, as desired. In one embodiment, the connector launch pin 210 may be attached to the PCB after attachment of the attachment member 220, e.g., during the automated attachment process, although other embodiments where the pin is attached after that process are also envisioned.

Thus, upon attachment of the connector launch 200 to the PCB 280 and attachment of the screw cap 250 to the screw cap receptacle 230, an enclosure may be formed, e.g., providing isolation between the external environment and the coupling between the at least one trace 290 and the connector launch pin 210.

The embodiment shown in FIG. 3A demonstrates a variation in which the at least one trace may be allowed to exit the first attachment member without use of a via. In particular, FIG. 3A illustrates an example embodiment in which a “mouse hole” has been carved out of the first attachment member to allow for such a trace exit. However, embodiment using via or other mechanisms for the at least one trace are also envisioned.

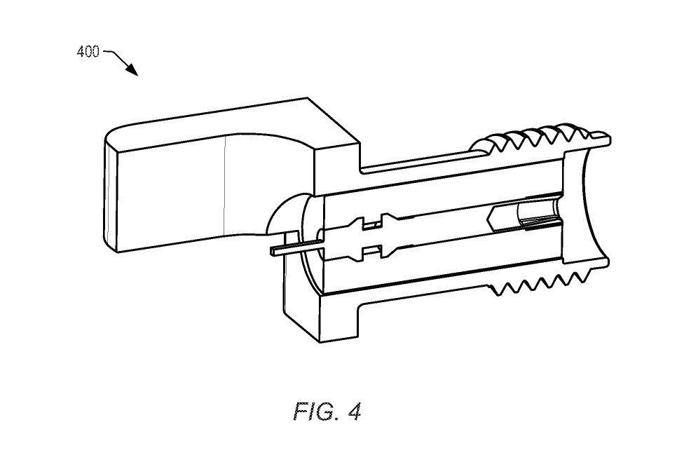

FIG. 4 illustrates an alternative embodiment of a connector launch 400, where the connector and pins are comprised in the connector launch 400 and are not provided in modular form. However, such an embodiment may not provide some of the mechanical isolation and end-user flexibility discussed above.

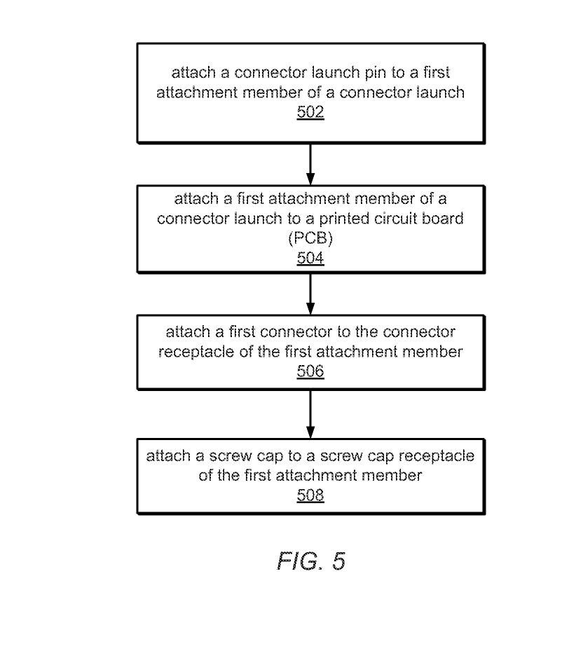

### FIG. 5

### Attachment of a Connector Launch

FIG. 5 illustrates a method for attaching a connector launch to a printed circuit board (PCB). The method shown in FIG. 5 may be used in conjunction with any of the systems shown in the above Figures, among other systems or apparatus. In various embodiments, some of the method elements shown may be performed concurrently, in a different order than shown, or may be omitted. Additional method elements may also be performed as desired. As shown, this method may operate as follows.

In 502 a connector launch pin may be attached to a first attachment member of a connector launch. As discussed above, the connector launch pin may be configured to couple to the at least one trace of a PCB within the first attachment member and extend into the connector receptacle of the connector launch. The connector launch pin may be configured to couple to a connector pin of the first connector when the first connector is connected to the connector receptacle. The connector launch pin may be attached to the first attachment member using a glass seal or bead (e.g., glass seal soldering or using any desired mechanically rigid dielectric material), although other attachment methods are also envisioned.

In 504 a first attachment member of the connector launch may be attached to the PCB. In one embodiment, the first attachment member may be attached to the PCB during primary component attachment, e.g., within an automated process. The attachment of 504 may be performed using soldering or a conductive adhesive, such as epoxy. The first attachment member may be attached using surface mount attachment (SMA).

Attaching the first attachment member to the PCB may include placing the first attachment member over at least one trace of the PCB, where the at least one trace of the PCB is configured for coupling to the connector launch. As discussed above, the first attachment member may include a connector receptacle that is configured to receive a first connector. In one embodiment, the connector receptacle may be configured to receive a plurality of possible connectors, i.e., the connector receptacle may be configured to receive a variety of different types of connectors, as desired.

While shown in the opposite order, the attachment of the connector launch pin in 502 may also be performed after the attachment of the first attachment member in 504. For example, in one embodiment, the attachment of the connector launch pin may be performed after an automated attachment process, e.g., of primary components to the PCB.

In 506, the first connector may be attached to the connector receptacle. In one embodiment, the first connector may not be attached to the connector receptacle until after the attachment of 502 and/or 504. This later attachment may allow the connector to avoid exposure to surface mount technology (SMT) temperatures. Because the first connector may be attached at a later time, it may be field replaceable by end users.

In some embodiments, the first attachment member comprises a screw cap receptacle for receiving a screw cap to form an enclosure over the at least one trace of the PCB after attachment to the PCB. Accordingly, in such embodiments, the method may include, in 508, attaching the screw cap to the screw cap receptacle.

Although the embodiments above have been described in considerable detail, numerous variations and modifications will become apparent to those skilled in the art once the above disclosure is fully appreciated. It is intended that the following claims be interpreted to embrace all such variations and modifications.

1. A connector launch configured for attachment to a printed circuit board (PCB), comprising:
a first attachment member, configured for surface mount attachment over at least one trace of the PCB, wherein the at least one trace of the PCB is configured for coupling to the connector launch, wherein the first attachment member comprises a connector receptacle, wherein the connector receptacle is configured to receive a first connector of a plurality of possible connectors, and wherein the first attachment member comprises a screw cap receptacle for receiving a screw cap to form an enclosure over the at least one trace of the PCB after attachment to the PCB, wherein the connector launch further comprises the screw cap; and
a connector launch pin configured to couple to the at least one trace of the PCB within the first attachment member and extend into the connector receptacle for coupling to a connector pin of the first connector when the first connector is connected to the connector receptacle.

2. (canceled)

3. The connector launch of claim 1, wherein the connector launch pin is configured to be attached to the first attachment member by a mechanically rigid dielectric material.

4. The connector launch of claim 1, wherein the connector receptacle is threaded coaxially.

5. The connector launch of claim 1, wherein the first attachment member is configured for surface mount attachment during primary component attachment to the PCB.

6. The connector launch of claim 1, wherein the surface mount attachment is performed in an automated fashion.

7. The connector launch of claim 1, wherein the PCB comprises a PCB assembly (PCA).

8. A printed circuit board assembly (PCA), comprising:
at least one trace for coupling to a connector launch;
the connector launch coupled to the at least one trace, comprising:
a first attachment member, configured for attachment over the at least one trace of the PCA, wherein the first attachment member comprises a connector receptacle, wherein the connector receptacle is configured to receive a first connector of a plurality of possible connectors, and wherein the first attachment member comprises a screw cap receptacle for receiving a screw cap to form an enclosure over the at least one trace of the PCA, wherein the connector launch further comprises the screw cap; and
a connector launch pin configured to couple to the at least one trace of the PCB within the first attachment member and extend into the connector receptacle for coupling to a connector pin of the first connector when the first connector is connected to the connector receptacle.

9. The PCA of claim 8, further comprising:
the first connector.

10. (canceled)

11. The PCA of claim 8, wherein the connector launch pin is configured to be attached to the first attachment member by a mechanically rigid dielectric material.

12. The PCA of claim 8, wherein the connector receptacle is threaded coaxially.

13. The PCA of claim 8, wherein the first attachment member is configured for surface mount attachment during primary component attachment to the PCA.

14. The PCA of claim 8, wherein the surface mount attachment is performed in an automated fashion.

15. A method of attaching a connector launch to a printed circuit board (PCB), comprising:
during primary component attachment, attaching the connector launch to the PCB, wherein attaching the connector launch to the PCB comprises placing a first attachment member of the connector launch over at least one trace of the PCB, wherein the at least one trace of the PCB is configured for coupling to the connector launch, wherein the first attachment member comprises a connector receptacle, wherein the connector receptacle is configured to receive a first connector of a plurality of possible connectors, and wherein the first attachment member comprises a screw cap receptacle for receiving a screw cap to form an enclosure over the at least one trace of the PCB after attachment to the PCB;
attaching a connector launch pin to the PCB, wherein the connector launch pin is configured to couple to the at least one trace of the PCB within the first attachment member and extend into the connector receptacle for coupling to a connector pin of the first connector when the first connector is connected to the connector receptacle.

16. The method of claim 15, wherein said attaching the connector launch is performed during an automated attachment process.

17. The method of claim 15, wherein the method further comprises:
attaching the screw cap to the screw cap receptacle.

18. The method of claim 15, further comprises:
attaching the first connector to the connector receptacle.

19. The method of claim 15, wherein said attaching the connector launch pin to the first attachment member by a mechanically rigid dielectric material.

20. The method of claim 15, wherein the connector receptacle is threaded coaxially.
